(19) United States
(12) Patent Application Publication
(10) Pub. No.: US 2024/0080003 A1
(43) Pub. Date: Mar. 7, 2024

(54) DIGITAL RF AMPLIFIER

(71) Applicant: Ampleon Netherlands B.V., Nijmegen (NL)

(72) Inventors: Johannes Adrianus Maria De Boet, Nijmegen (NL); Daniel Maassen, Nijmegen (NL); Rob Mathijs Heeres, Nijmegen (NL)

(21) Appl. No.: 18/458,545

(22) Filed: Aug. 30, 2023

(30) Foreign Application Priority Data
Sep. 1, 2022 (NL) 2032932

(51) Int. Cl. H03F 3/19; H04B 1/04

(52) U.S. Cl. CPC H03F 3/19; H04B 1/04; H03F 2200/451

(57) ABSTRACT

Example embodiments relate to digital RF amplifiers. One example digital RF amplifier includes a driver having a plurality of outputs and being configured to individually set a signal level at the outputs either to an inactive or active level in response to a digital input signal. The RF amplifier also includes a transistor configured to output an analog RF signal at a transistor output. The transistor includes a plurality of transistor cells, each including a control terminal, an output terminal, and a common terminal. The transistor also includes a plurality of transistor inputs, each transistor input being electrically connected to the control terminal of at least one transistor cell. The transistor inputs are mutually electrically isolated. Each transistor input is connected to a different output of the driver. The transistor output is electrically connected to the output terminals of the plurality of transistor cells. The transistor is a circular transistor.

### CROSS-REFERENCE TO RELATED APPLICATIONS

The present application is a non-provisional patent application claiming priority to Netherlands Patent Application No. NL 2032932, filed Sep. 1, 2022, the contents of which are hereby incorporated by reference.

### FIELD OF THE DISCLOSURE

The present disclosure is related to a digital radiofrequency, RF, amplifier. The present disclosure is particularly related to a digital transmitter in which the digital RF amplifier is used. The digital RF amplifier can for example be used in high-speed and high-power applications, such as 5G mMIMO base stations.

Within the context of the present disclosure, a digital RF amplifier is an amplifier that receives a digital input signal and outputs an analog signal, more in particular an analog RF signal.

### BACKGROUND

Digital RF amplifiers are known in the art. An example thereof is schematically shown in FIG. 1. In this figure, digital RF amplifier 20 comprises a driver 10 that receives a digital input signal IN. Driver 10 generates a plurality of control signals that are fed to respective transistor inputs 2 of a transistor 1 that is divided into a plurality of segments or cells 4. Each transistor input 2 is connected to a respective cell 4.

The control signals can either have an active level, in which the application of the control signal causes the connected transistor cell 4 to become saturated, or an inactive level, in which the application of the control signal causes connected transistor cell 4 to switch off and/or to not output any signal. The outputs of transistors cells 4 are combined into an RF output signal, RF out, emerging at transistor output 3.

In the example of FIG. 1, transistor 1 comprises six transistor inputs 2 for controlling six individual and identical transistor cells 4. Using this configuration, and assuming that each transistor cell 4 is either outputting its associated maximum output power or no output at all, a maximum total of 2\hat{ }6=64 values are possible for the power of the analog RF signal outputted by transistor 1. Practical digital amplifiers may have many more transistor cells, e.g. 1024.

A detail of a known implementation of a transistor 1 for a digital amplifier, such as digital RF amplifier 20, is shown in FIG. 2. Here, part of a multi-finger transistor 1 is shown, wherein transistor 1 comprises a plurality of finger-shaped drain regions 5 (only one shown), a plurality of finger-shaped gate regions 6, and a plurality of source regions 7, wherein source regions 7 are generally connected to each other. Each combination of a drain region 5, gate region 6, and source region(s) 7 constitutes a transistor cell 4. More in particular, the drain region 5 of each transistor cell 4 forms an output terminal of that cell, the gate region 6 of each transistor cell 4 a control terminal, and the source region(s) 7 a common terminal.

As shown, source regions 7 are interrupted to allow a connection to be made between transistor inputs 2 of transistor 1 and gate regions 6. Furthermore, all drain regions 5 of transistor 1 are electrically connected to each other and to transistor output 3 (not shown).

In FIG. 2, each transistor input 2 is connected to a single gate region 6 of a single transistor cell 4. By driving transistor inputs 2, the various transistor cells 4 of transistor 1 can be activated thereby determining the power outputted by transistor 1.

To reduce Ohmic losses and/or resistance, gate regions 6 can be connected to finger-shaped metal structures. As gate regions 6 are relatively narrow, a via connection with an upper-lying metal layer of the finger-shaped metal structure is not possible. For that reason, the connection between the finger-shaped metal structures and the various gate regions 6 is typically realized in the regions where source regions 7 are interrupted. In these regions, relatively wide patches are formed that are connected to gate regions 6 and that allow a via connection with an upper-lying metal layer. The finger-shaped metal structures connected to gate regions 6, if used, are referred to as gate runners.

Drain regions 5 can also be connected to finger-shaped metal structures for reducing Ohmic losses and/or resistance. Typically, drain regions 5 are sufficiently wide to allow a via connection with an upper-lying metal layer.

FIG. 3 illustrates an implementation of a digital RF amplifier 20A based on polar modulation that is known from WO 2021162545 A1. Here, driver 10A of digital amplifier 20A comprises a first logic unit 11A that receives digital data IN and that generates digital magnitude ρ and phase θ values. The magnitude values are fed to a digital word generator 12A that generates a digital word based on the received magnitude value.

Clock generator 13A generates a clock signal, such as a pulse signal, having a constant frequency but with a phase offset that depends on the received phase value. The generated digital word and generated clock signal are fed to a second logic unit 14A that generates control signals to be fed to the transistor cells 4A of transistor 1A. Second logic unit 14A comprises a plurality of cells 141A, wherein each cell 141A generates a respective control signal for a respective transistor cell 4A in dependence of the clock signal and a respective bit of the generated digital word. For example, the control signal may have an active level when both the corresponding bit of the generated digital word and the clock signal have a logical high value, and an inactive level when either the corresponding bit of the generated digital word or the clock signal has a logical low value.

FIG. 4 illustrates a known implementation of a digital amplifier 20B based on quadrature amplitude modulation. In this embodiment, first logic unit 11B generates digital in-phase signals I and quadrature signals Q based on digital input data IN. Clock generator 13B generates a clock signal, such as a pulse signal, having a constant frequency. The clock signal is fed to a primary second logic unit 14B_1. It is also fed to a secondary second logic unit 14B_2, albeit with a phase offset of −90 degrees relative to primary second logic unit 14B_1.

Primary digital word generator 12B_1 generates a first digital word based on the received I signal and secondary digital word generator 12B_2 generates a second digital word based on the received Q signal.

Primary and secondary second logic unit 14B_1, 14B_2 operate as second logic unit 14A of digital amplifier 20A shown in FIG. 3. The respective control signals are fed to respective transistor cells 4B_1, 4B_2 of transistors 1B_1, 1B_2, respectively, of which the analog output signals are combined. Each of the transistors 1B_1 and 1B_2 is similar to transistor 1A shown in FIG. 3 and transistor 1 shown in FIG. 2.

For proper control of the output power, and to achieve high gain and efficiency values for the digital amplifier, it is important that the transistor inputs can be driven separately. The Applicant has found that these objectives are difficult to achieve with the layout of the transistor shown in FIG. 2.

US 2003/218185A1 discloses a semiconductor device using an emitter top heterojunction bipolar transistor formed above a semiconductor substrate and having a planar shape in a ring-like shape. A structure is provided in which a base electrode is present only on an inner side of a ring-like emitter-base junction region.

### SUMMARY

An object of the present disclosure is to provide a digital RF amplifier in which the abovementioned problem is at least partially solved. This object is achieved with a digital RF amplifier as defined in claim 1 that is characterized in that the transistor is a circular transistor of which the control terminal and the output terminal of each transistor cell have a circular geometry and are concentrically arranged.

The Applicant has found that electromagnetic coupling between ends of adjacently arranged gate regions, as indicated in region R in FIG. 2, has a deteriorating effect on the isolation between the different transistor inputs. The Applicant further found that in topologies in which a drain region is shared among adjacent transistor cells, it is more difficult to individually control the behavior of the adjacent transistor cells. The Applicant has found that by using transistor cells having a circular geometry, coupling between different transistor inputs and/or different transistor cells can be mitigated, and performance of the digital RF amplifier can be improved.

The driver can be configured, when setting the signal level at a given output to the active level, to drive the at least one transistor cell corresponding to said given output into saturation. According to the disclosure, each output of the driver is connected to a respective transistor input. However, each transistor output can be connected to one or a plurality of transistor cells. Additionally or alternatively, all transistor cells are identical.

The control terminals of the plurality of transistor cells may have equal widths measured along a circumferential direction. Similarly, the control terminals of the plurality transistor cells may have equal lengths measured in a radial direction.

The driver can be configured to set a signal level at the outputs such that the number of outputs for which the signal level is set to the active level corresponds to a signal amplitude of the analog RF signal to be outputted. This is particularly useful when the total width of the control terminal associated with each transistor cell is identical. However, the total width of the control terminal for the transistor cells may be different. For example, by using a combination of relatively small and large transistor cells, an improvement in resolution can be obtained with respect to the signal amplitude. For example, in an embodiment wherein 5 transistor inputs are used that are each connected to a single transistor cell, and if 5 transistor cells are used that can output 1 W, 2 W, 2 W, 5 W, 10 W, respectively, it becomes possible to generate an analog RF output signal having a power between OW and 20 W with increments of 1 W. In an embodiment wherein 5 transistor cells are used that are each connected to a respective transistor input, and that can each output 4 W, it becomes possible to generate an analog RF output signal having a power between OW and 20 W with increments of 4 W. This improvement in resolution can also be used if the 5 transistor inputs are connected to respectively 1, 2, 2, 5, and 10 transistor cells that each have a saturated output power of 1 W.

The digital amplifier may further comprise a conductive semiconductor substrate on which an epitaxial layer is arranged. The transistor can be integrated on and/or in the epitaxial layer, wherein the common terminals of all transistor cells are electrically connected to the conductive semiconductor substrate by means of one or more vias or highly doped regions extending between the common terminals and the conductive semiconductor substrate. Furthermore, the transistor cells may each form a Silicon-based laterally diffused metal oxide semiconductor, LDMOS, transistor. A width of the smallest control terminal among the transistor cells may then lie in a range between 10 and 100 micrometer, preferably between 10 and 50 micrometer.

Alternatively, the digital amplifier may comprise an isolating semiconductor substrate on which an epitaxial layer is arranged, wherein the transistor is integrated on and/or in the epitaxial layer. The transistor may further comprise a further transistor output electrically connected to the common terminals of the plurality of transistor cells. The transistor cells may each form a Gallium Nitride-based high electron mobility transistor. A width of the smallest control terminal among the transistor cells may then lie in a range between 10 and 100 micrometer, preferably between 10 and 50 micrometer.

For each transistor cell, the control terminal may surround the output terminal. For each such transistor cell the control terminal may comprise an island that extends radially away from a remainder of the control terminal through a passage between two regions of the common terminal of that transistor cell or over the common terminal of that transistor cell.

Alternatively, for each transistor cell the output terminal may surround the control terminal. A connection between each transistor input and a control terminal it is connected to may extend over the output terminal that corresponds to that control terminal and is separated from that output terminal by one or more dielectric layers.

In case the output terminal surrounds the control terminal and the abovementioned isolating semiconductor substrate is used, a connection between the further transistor output and a common terminal it is connected to may extend over the control terminal and the output terminal that corresponds to that common terminal and may be separated from the control terminal and the output terminal by one or more dielectric layers.

The driver may be flip-chipped onto the transistor. To this end, the transistor inputs of the transistor may each comprise a respective pad, and the outputs of the driver may each comprise a respective pad, wherein the pad of each transistor input is connected to the pad of a respective output of the driver, for example using a solder ball or other type of conductive connection. The solder balls may have a diameter ranging from 10 to 80 micrometer.

According to a second aspect of the present disclosure, a digital transmitter is provided that comprises an antenna and the digital RF amplifier described above, wherein the digital RF amplifier is configured to output the analog RF signal to the antenna.

### BRIEF DESCRIPTION OF THE DRAWINGS

Next, example embodiments will be described in more detail referring to the appended drawings, wherein identical or similar components will be referred to using identical reference signs.

FIG. 1 is a schematic illustration of a known digital amplifier.

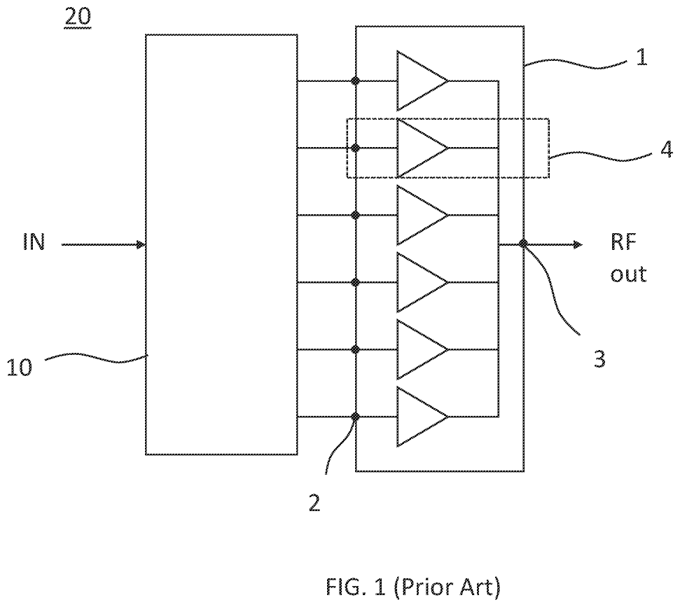

FIG. 2 shows a known implementation of a transistor for the digital amplifier of FIG. 1.

FIG. 3 illustrates an implementation of a known digital amplifier based on polar modulation.

FIG. 4 illustrates a known implementation of a digital amplifier based on quadrature amplitude modulation.

FIG. 5 illustrates a first and second example of a transistor cell used in a transistor, according to example embodiments.

FIG. 6 illustrates a detailed layout of a transistor corresponding to the first example of FIG. 5.

FIG. 7 illustrates a detailed layout of a transistor corresponding to the second example of FIG. 5.

FIG. 8 illustrates an embodiment of a digital RF amplifier, according to example embodiments.

### DETAILED DESCRIPTION

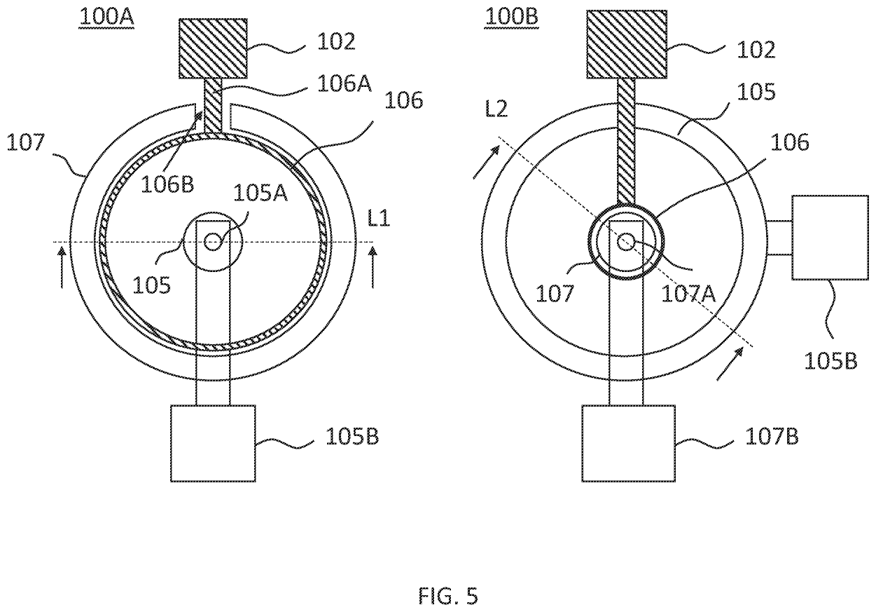

FIG. 5, left, illustrates a first example of a transistor cell 100A that can be used in a transistor in accordance with the present disclosure.

Transistor cell 100A corresponds to an LDMOS transistor and comprises a gate pad 102 that connects to a ring-shaped gate region 106. In FIG. 5, left, gate pad 102 forms an input of the transistor. Alternatively, gate pads 102 of adjacently arranged transistor cells 100A are electrically connected to a single transistor input. The connection between gate pad 102 and gate region 106 comprises an island 106A that passes through a clearance or passage 106B in source region 107. Furthermore, gate region 106 surrounds a circular drain patch 105 that forms the drain region. Using a via 105A, patch 105 connects to a higher metal layer in which a drain pad 105B is realized. Drain pads 105B of the various transistor cells 100A of transistor 1 are electrically connected.

Ring-shaped gate region 106 is typically realized using a relatively thin conductive layer, such as a polysilicon layer, whereas gate pad 102 is realized using a relatively thick layer. To this end, transistor cell 100A is realized using a layer stack of conductive layers, wherein the upper layers are relatively thick. Connection between the different layers of the layer stack is possible using well-known vias.

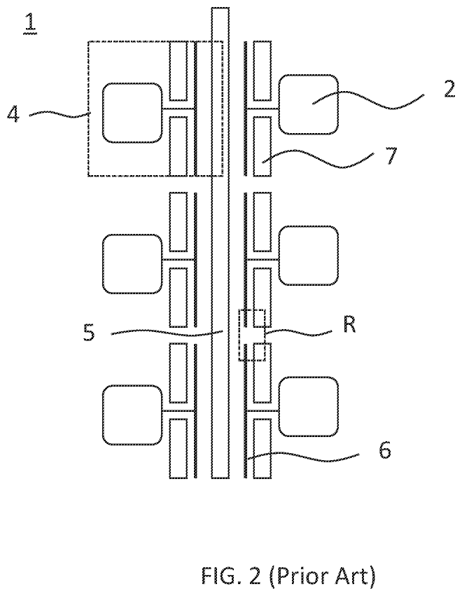

As may be appreciated from the figure, gate regions 106 of neighboring transistor cells 100A are much less likely to couple electromagnetically when compared to the known transistor cell layout shown in FIG. 2. This can be attributed, at least partially, to the shielding of source region 107. Furthermore, a circular drain patch 105 of one transistor cell 100A is not involved in the electrical operation of another transistor cell 100A in the same manner as drain region 5 in FIG. 2.

In this example, it is assumed that the conductive substrate on which transistor cell 100A is realized is conductive. This allows a connection of source region 107 to ground through the substrate. In case the substrate is isolating, a via extending through the substrate could be used provided such technology is available for the semiconductor material system that is used for transistor cell 100A. For LDMOS transistors, the substrate typically comprises conductive Silicon substrates.

Typical dimensions of transistor cell 100A include an inner diameter of source region 107 in a range between 4 and 12 micrometer, an outer diameter of ring-shaped gate finger 106 in a range between 4 and 12 micrometer, and an outer diameter of circular drain patch 105 in a range between 1.5 and 4 micrometer. Typically, a source-gate separation lies in a range between 0.7 and 5, and a gate-drain separation in a range between 1 and 4 micrometer.

It is further noted that transistor cell 100A is realized on a Silicon semiconductor die having a conductive substrate and one or more epitaxial layers formed thereon. A cross section taken along line L1 corresponds to the cross section of known LDMOS transistors.

FIG. 5, right, illustrates a second example of a transistor cell 100B that can be used in a transistor in accordance with the present disclosure. In this cell, ring-shaped gate region 106 surrounds a circular source patch 107, which patch 107 is connected through a via 107A to an upper-lying metal layer that connects to and/or is integrally formed with a source pad 107B. Ring-shaped drain region 105 surrounds ring-shaped gate region 106 and is connected to a drain pad 105B. Drain pads 105B of the various transistor cells 100B of transistor 1 are electrically connected. Similarly, source pads 107B of the various transistor cells 100B of transistor 1 are electrically connected.

In this embodiment, connection between source patch 107 and ground is realized through source pad 107B. This transistor cell 100B can therefore be used on isolating substrates.

Transistor cells 100B are typically spaced apart from each other in such a manner that drain regions 105 do not touch each other.

Similar to transistor cell 100A, the transistor action is localized within the circular geometry of the transistor cell 100B itself and does not interfere with the transistor action of an adjacent transistor cell 100B.

To prevent short-circuits between the various contacts in transistor cells 100A, 100B, dielectric crossovers or air-bridges may be used in a manner known in the art.

It is further noted that transistor cell 10BA is realized on a Gallium Nitride, GaN, die having a isolating substrate and one or more epitaxial layers formed thereon. A cross section taken along line L2 corresponds to the cross section of known GaN HEMTs.

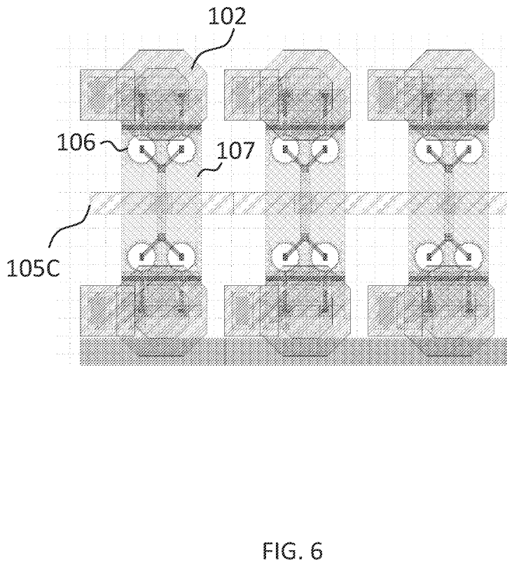

FIG. 6 illustrates a detailed layout corresponding to transistor cell 100A of FIG. 5. As shown, each gate pad 102 forms a respective transistor input and is connected to the ring-shaped gate regions 106 of two transistor cells 100A. In addition, the circular drain patches 105 are connected to a drain runner 105C. Here, drain runner 105C comprises a track formed in a typically thick metal layer that is connected to the drain regions 105 of the transistor cells 100A. In FIG. 6, drain runner 105C is connected to 12 circular drain patches 105. Furthermore, source regions 107 of the different transistor cells 100A are connected together.

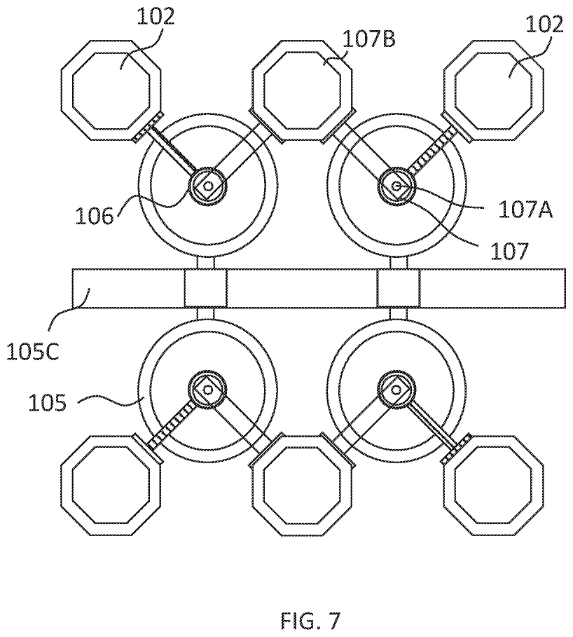

FIG. 7 illustrates a detailed layout corresponding to transistor cell 100B of FIG. 5. As shown, each gate pad 102 forms a respective transistor input and is connected to the ring-shaped gate regions 106 of two transistor cells 100B (only one connection shown). In addition, the circular drain patches 105 are connected to a drain runner 105C. In FIG. 7, drain runner 105C is connected to 4 circular drain patches 105. Furthermore, source regions 107 of 2 different transistor cells 100B are connected together using source pad 107B.

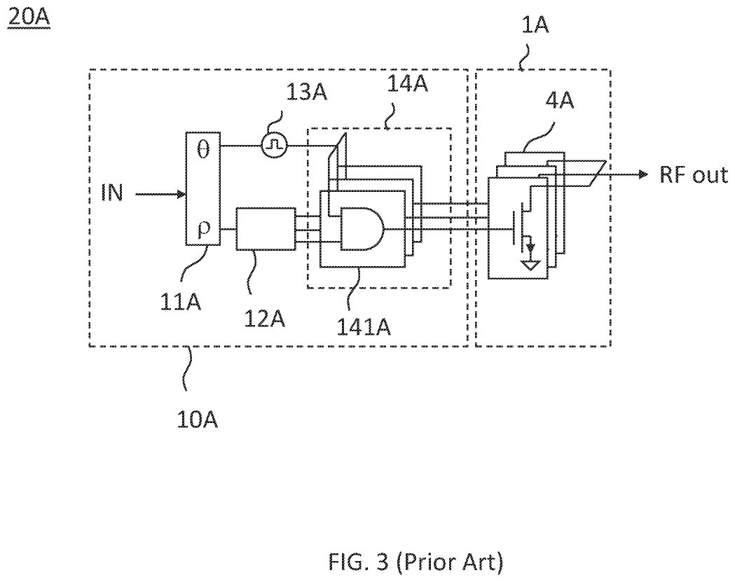

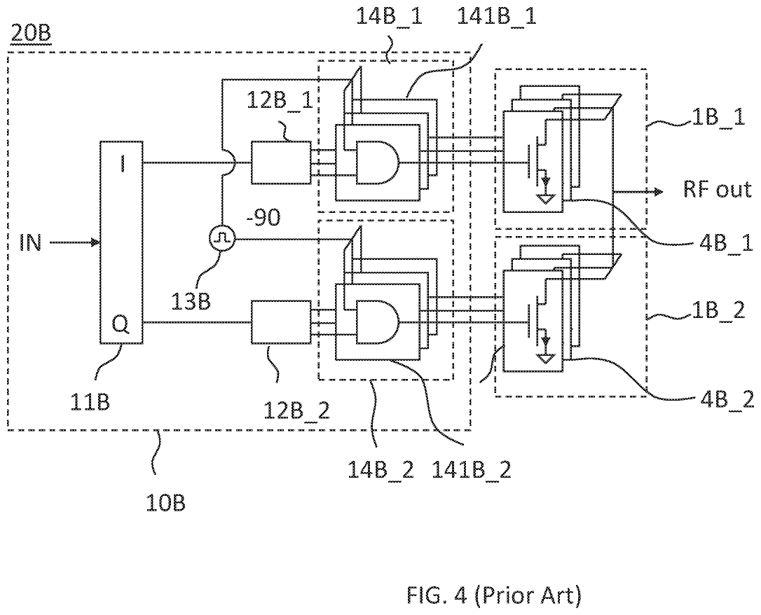

A transistor in accordance with the present disclosure comprises a plurality of transistor cells, such as transistor cell 100A or transistor cell 100B. Such transistor can be used in the topology of FIG. 3 or 4. In such case, the driver, which is typically implemented in CMOS, can be flip-chipped onto the transistor. To this end, gate pads 102 may be connected to respective outputs of the driver using solder balls. Part of the transistor may correspond to the layout shown in FIG. 6 or 7.

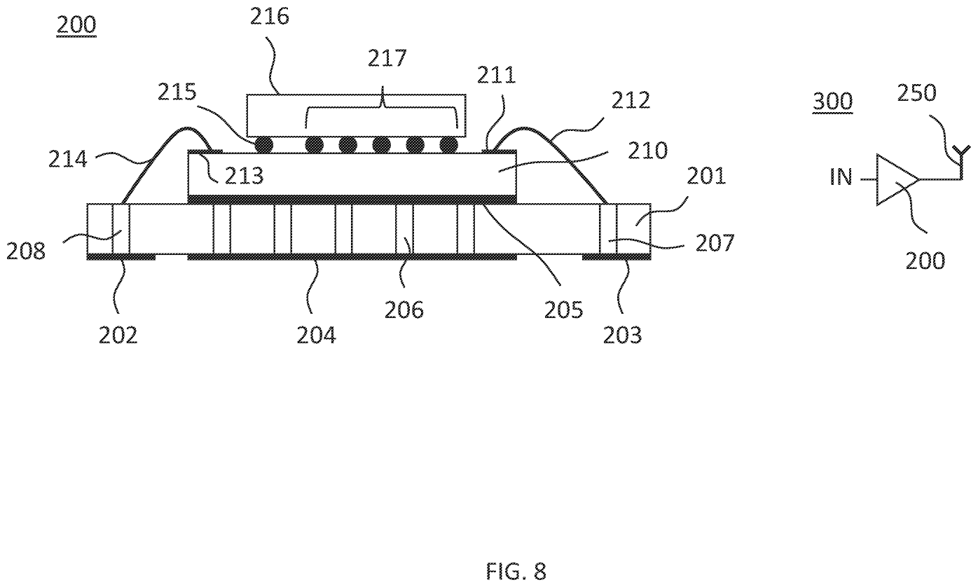

FIG. 8 illustrates an embodiment of a digital RF amplifier 200 in accordance with the present disclosure. It comprises a printed circuit board 201 on which on the backside a land grid array, LGA, pattern is formed. This pattern comprises a first pad 202 for inputting a digital input signal, a second pad 203 for outputting an analog RF signal, and a central pad 204 for connecting to electrical ground. Central pad 204 is connected to a die pad 205 arranged on the opposing surface of PCB 201 using a plurality of vias 206.

A semiconductor die 210, in or on which the transistor in accordance with the present disclosure is integrated, is arranged on die pad 205. In FIG. 6, an LDMOS transistor is implemented. Furthermore, semiconductor die 210 comprises a conductive substrate allowing an electrical connection between the common terminals 107 of the transistor cells of the LDMOS transistor and die pad 205 without the use of via technology.

On the top surface of semiconductor die 210 a pad 211 is provided that is electrically connected to the transistor output and therefore to output terminals 105 of the various transistor cells of the LDMOS transistor. Pad 211 is connected, using a bondwire 212, to a pad (not shown) on PCB 201. This latter pad is connected to pad 203 through a via 207.

On the top surface of semiconductor die 210 a pad 213 is provided that is electrically connected, through a bondwire 214, to a pad (not shown) on PCB 201. This latter pad is connected to pad 202 through a via 208.

Pad 213 is electrically connected to a solder ball 215 that makes a connection to the input of the driver 10 that is integrated on and/or in semiconductor die 216, which is flip-chipped onto semiconductor die 210. The outputs of driver 10 are connected, using solder balls 217, to the transistor inputs of the LDMOS transistor realized on semiconductor die 210.

It should be noted that other connections, such as a connection for providing a supply voltage, are not shown in FIG. 8. Furthermore, FIG. 8 illustrates but one possible implementation of a digital RF amplifier in accordance with the present disclosure. For example, lead-frame bases solutions are equally possible.

FIG. 8 further illustrates an embodiment of a digital transmitter 300 in accordance with the present disclosure. It comprises an antenna 250 and the digital RF amplifier according to the present disclosure, for example digital RF amplifier 200. Here, digital RF amplifier 200 receives a digital input signal, IN, and outputs an analog RF signal to antenna 250.

In the above, detailed embodiments were explained. However, the present disclosure is not limited to these embodiments. Various modifications are possible without deviating from the scope of the present disclosure, which is defined by the appended claims and their equivalents.

What is claimed is:

1. A digital radiofrequency, RF, amplifier, comprising:
a driver having a plurality of outputs and being configured to individually set a signal level at the outputs either to an inactive level or to an active level in response to a digital input signal; and
a transistor configured to output an analog RF signal at a transistor output, the transistor comprising:
a plurality of transistor cells, each transistor cell comprising a control terminal, an output terminal, and a common terminal; and
a plurality of transistor inputs, each transistor input being electrically connected to the control terminal of at least one transistor cell, wherein the transistor inputs are mutually electrically isolated, wherein each transistor input is connected to a different output of the driver,
wherein the transistor output is electrically connected to the output terminals of the plurality of transistor cells, and
wherein the transistor is a circular transistor of which the control terminal and the output terminal of each transistor cell have a circular geometry and are concentrically arranged.

2. The digital RF amplifier according to claim 1, wherein the driver is configured, when setting the signal level at a given output to the active level, to drive the at least one transistor cell corresponding to said given output into saturation.

3. The digital RF amplifier according to claim 1, wherein a momentary value of the digital input signal is representative for the momentary amplitude of the analog RF signal to be outputted.

4. The digital RF amplifier according to claim 1, wherein the control terminals of the plurality of transistor cells have equal widths measured along a circumferential direction.

5. The digital RF amplifier according to claim 4, wherein the driver is configured to set a signal level at the outputs such that the number of outputs for which the signal level is set to the active level corresponds to a signal amplitude of the analog RF signal to be outputted.

6. The digital RF amplifier according to claim 1, further comprising a conductive semiconductor substrate on which an epitaxial layer is arranged, wherein the transistor is integrated on and/or in the epitaxial layer, and wherein the common terminals of all transistor cells are electrically connected to the conductive semiconductor substrate by means of one or more vias or highly doped regions extending between the common terminals and the conductive semiconductor substrate.

7. The digital RF amplifier according to claim 6, wherein the transistor cells each form a Silicon-based laterally diffused metal oxide semiconductor, LDMOS, transistor.

8. The digital RF amplifier according to claim 7, wherein a width of the smallest control terminal among the transistor cells lies in a range between 10 and 100 micrometer.

9. The digital RF amplifier according to claim 1, further comprising an isolating semiconductor substrate on which an epitaxial layer is arranged, wherein the transistor is integrated on and/or in the epitaxial layer, and wherein the transistor further comprises a further transistor output electrically connected to the common terminals of the plurality of transistor cells.

10. The digital RF amplifier according to claim 9, wherein the transistor cells each form a Gallium Nitride-based high electron mobility transistor.

11. The digital RF amplifier according to claim 10, wherein a width of the smallest control terminal among the transistor cells lies in a range between 10 and 100 micrometer.

12. The digital RF amplifier according to claim 1, wherein for each transistor cell the control terminal surrounds the output terminal.

13. The digital RF amplifier according to claim 12, wherein for each transistor cell the control terminal comprises an island that extends radially away from a remainder of the control terminal through a passage between two regions of the common terminal of that transistor cell or over the common terminal of that transistor cell.

14. The digital RF amplifier according to claim 1, wherein for each transistor cell the output terminal surrounds the control terminal.

15. The digital RF amplifier according to claim 14, wherein a connection between each transistor input and a control terminal it is connected to extends over the output terminal that corresponds to that control terminal and is separated from that output terminal by one or more dielectric layers.

16. The digital RF amplifier according to claim 14, further comprising an isolating semiconductor substrate on which an epitaxial layer is arranged, wherein the transistor is integrated on and/or in the epitaxial layer, wherein the transistor further comprises a further transistor output electrically connected to the common terminals of the plurality of transistor cells, and
wherein a connection between the further transistor output and a common terminal it is connected to extends over the control terminal and the output terminal that correspond to that common terminal and is separated from the control terminal and output terminal by one or more dielectric layers.

17. The digital RF amplifier according to claim 1, wherein the driver is flip-chipped onto the transistor.

18. The digital RF amplifier according to claim 17, wherein the transistor inputs of the transistor each comprise a respective pad, wherein the outputs of the driver each comprise a respective pad, and wherein the pad of each transistor input is connected to the pad of a respective output of the driver.

19. The digital RF amplifier according to claim 1, wherein the control terminal is a gate, the output terminal is a drain, and the common terminal is a source, or
wherein the control terminal is a base, the output terminal is a collector, and the common terminal is an emitter.

20. A digital transmitter, comprising:
an antenna; and
the digital RF amplifier according to claim 1, wherein the digital RF amplifier is configured to output the analog RF signal to the antenna.
